(19) United States
(12) Patent Application Publication
(10) Pub. No.: US 2026/0293615 A1
(43) Pub. Date: Sep. 24, 2026

(54) SEMICONDUCTOR CHIP AND SEMICONDUCTOR PACKAGE

(71) Applicant: Samsung Electronics Co., Ltd., Suwon-si (KR)

(72) Inventors: Aenee Jang, Seoul (KR); Yoonsung Kim, Seoul (KR); Seungduk Baek, Hwaseong-si (KR); Yunrae Cho, Guri-si (KR)

(73) Assignee: Samsung Electronics Co., Ltd., Suwon-si (KR)

(21) Appl. No.: 19/680,905

(22) Filed: May 18, 2026

Related U.S. Application Data
(63) Continuation of application No. 17/839,675, filed on Jun. 14, 2022, now Pat. No. 12,666,930.

(30) Foreign Application Priority Data
Sep. 23, 2021 (KR) 10-2021-0125570

(51) Int. Cl. H10P 74/00; H10W 72/90; H10W 90/00

(52) U.S. Cl. CPC H10P 74/273; H10W 90/00; H10W 72/923; H10W 72/934; H10W 90/792

(57) ABSTRACT

A method for manufacturing a semiconductor package includes forming a semiconductor wafer including a substrate having main regions and a scribe region between the main regions, a wiring structure on the main regions, at least one test wiring structure on the scribe region, a low dielectric layer, an input/output pad on the wiring structure, at least one test pad on the at least one test wiring structure, and a first insulating layer,, performing an electrical test through the at least one test pad, forming a second insulating layer on the first insulating layer, forming a connection pad in the second opening, forming a recess extending from an upper surface of the second insulating layer toward the partial region,, and dicing the semiconductor wafer along a dividing lane.

### CROSS-REFERENCE TO RELATED APPLICATIONS

This application is a continuation of U.S. application Ser. No. 17/839,675, filed on Jun. 14, 2022, which claims the priority and benefit of Korean Patent Application No. 10-2021-0125570, filed on Sep. 23, 2021, with the Korean Intellectual Property Office, the entire contents of each of which are incorporated herein by reference.

### BACKGROUND

### 1. Field

The present inventive concept relates to a semiconductor chip and a semiconductor package.

### 2. Description of Related Art

As the demand for high capacitance, thinness, and miniaturization of electronic products increases, various types of semiconductor packages are being developed. Recently, as a method to integrate more components (e.g., semiconductor chips) into a package structure, a direct bonding technology for bonding semiconductor chips without an adhesive film (e.g., NCF) or a connection bump (e.g., a solder ball) has been developed.

### SUMMARY

An aspect of the present inventive concept is to provide a semiconductor chip in which burrs protruding onto a bonding surface are reduced.

An aspect of the present inventive concept is to provide a semiconductor package in which void defects are minimized while a yield is improved during direct bonding.

According to an aspect of the present inventive concept, a semiconductor package is provided. The semiconductor package includes, a base structure including a body, an upper pad on the body, and an upper insulating layer on a side surface of the upper pad, the base structure having a planar upper surface provided by the upper insulating layer and the upper pad; and a semiconductor chip on the upper surface of the base structure, and including a substrate, a wiring structure below the substrate, a low dielectric layer on a side surface of the wiring structure, a lower connection pad below the wiring structure, and a lower insulating layer on a side surface of the lower connection pad, the semiconductor chip having a planar lower surface provided by the lower insulating layer and the lower connection pad, a side surface provided by the lower insulating layer and the substrate, and a recess surface extending from one end of the side surface to one end of the lower surface, wherein the low dielectric layer is spaced apart from the recess surface of the semiconductor chip by the lower insulating layer.

According to an aspect of the present inventive concept, a semiconductor package is provided. The semiconductor package includes: a base structure including an upper pad and an upper insulating layer on a side surface of the upper pad; and a semiconductor chip on the base structure, and including a substrate, a wiring structure below the substrate, a low dielectric layer on a side surface of the wiring structure, a lower connection pad below the wiring structure, and a lower insulating layer on a side surface of the lower connection pad, the semiconductor chip having a lower surface provided by the lower insulating layer and the lower connection pad, a side surface provided by the lower insulating layer and the substrate, and a recess surface extending from one end of the side surface to one end of the lower surface, wherein the recess surface includes a first surface recessed in a direction from the lower surface toward the substrate, and a second surface extending from the one end of the lower surface to the first surface, wherein the lower insulating layer extends between the first surface and the substrate.

According to an aspect of the present inventive concept, a semiconductor package is provided. The semiconductor package includes: a first semiconductor chip including a first substrate, a first upper connection pad on the first substrate, and a first upper insulating layer on a side surface of the first upper connection pad, the first semiconductor chip having a first upper surface provided by the first upper insulating layer and the first upper connection pad, and a first side surface provided by the first upper insulating layer; and a second semiconductor chip on the first upper surface of the first semiconductor chip, and including a second substrate, a second lower connection pad below the second substrate and facing the first upper connection pad, and a second lower insulating layer on a side surface of the second lower connection pad, the second semiconductor chip having a second lower surface provided by the second lower connection pad and the second lower insulating layer, a second side surface provided by the second lower insulating layer, and a lower recess surface extending from one end of the second side surface to one end of the second lower surface, wherein the lower recess surface is spaced apart from the second substrate.

According to an aspect of the present inventive concept, a semiconductor chip is provided. The semiconductor includes: a substrate having a front surface and a rear surface opposing each other; a circuit layer on the front surface of the substrate, and including a wiring structure and a low dielectric layer on a side surface of the wiring structure; and a front structure below the circuit layer, and including a lower connection pad electrically connected to the wiring structure, and a lower insulating layer on a side surface of the lower connection pad and the lower dielectric layer, the semiconductor chip having a planar lower surface provided by the lower insulating layer and the lower connection pad, a side surface provided by the lower insulating layer and the substrate, and a recess surface provided by the lower insulating layer and stepped inwardly from the lower surface and the side surface, respectively.

### BRIEF DESCRIPTION OF DRAWINGS

The above and other aspects, features, and advantages of the present inventive concept will be more clearly understood from the following detailed description taken in conjunction with the accompanying drawings, in which:

FIG. 1A is a perspective view illustrating a semiconductor package according to an example embodiment of the present inventive concept;

FIG. 1B is a cross-sectional view illustrating a cross-section taken along line I-I′ of FIG. 1A, and FIG. 1C is a partially enlarged view illustrating a region ‘A’of FIG. 1A;

FIG. 2A is a cross-sectional view illustrating a semiconductor package according to an example embodiment of the present inventive concept, and FIG. 2B is a partially enlarged view illustrating a region ‘B’of FIG. 2A;

FIG. 3A is a cross-sectional view illustrating a semiconductor package according to an example embodiment of the present inventive concept;

FIG. 3B is a partially enlarged view illustrating a region ‘C’of FIG. 3A;

FIG. 4A is a cross-sectional view illustrating a semiconductor package according to an example embodiment of the present inventive concept;

FIG. 4B is a partially enlarged view illustrating a region ‘D’of FIG. 4A;

FIG. 5 is a cross-sectional view illustrating a semiconductor package according to an example embodiment of the present inventive concept;

FIG. 6 is a cross-sectional view illustrating a semiconductor package according to an example embodiment of the present inventive concept;

FIGS. 7A to 7D are cross-sectional views illustrating a manufacturing process of a semiconductor chip according to a process sequence according to an example embodiment of the present inventive concept;

FIGS. 8A to 8D are cross-sectional views illustrating a manufacturing process of a semiconductor chip according to a process sequence according to an example embodiment of the present inventive concept; and

FIG. 9 is a cross-sectional view illustrating a manufacturing process of a semiconductor package according to an example embodiment of the present inventive concept.

### DETAILED DESCRIPTION

Hereinafter, example embodiments of the present inventive concept will be described with reference to the accompanying drawings as follows.

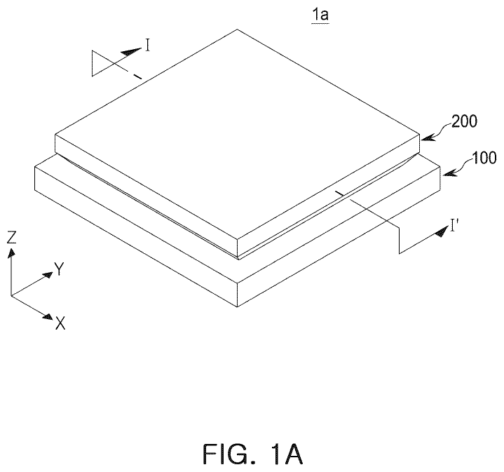

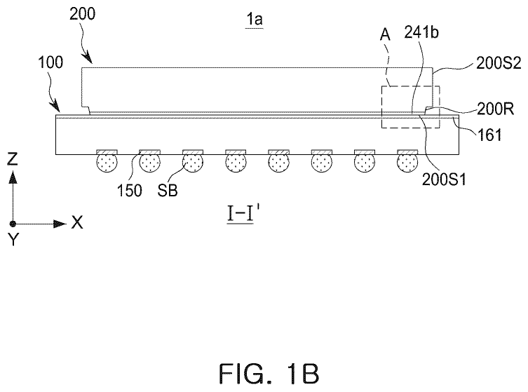

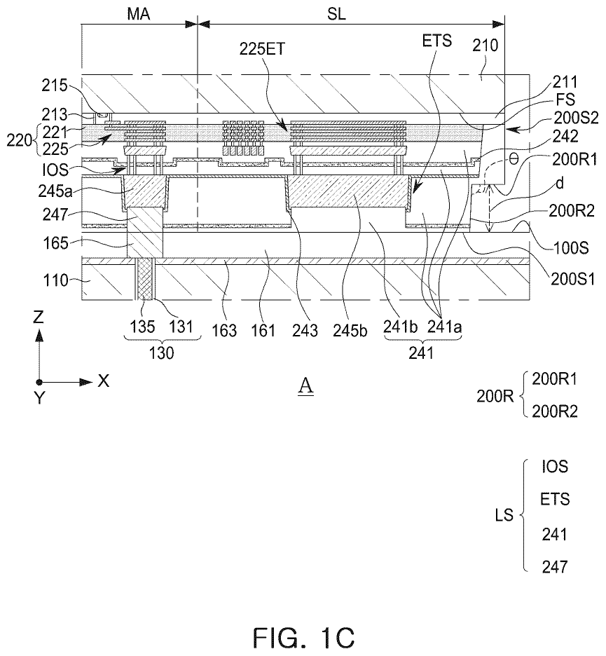

FIG. 1A is a perspective view illustrating a semiconductor package 1a according to an example embodiment of the present inventive concept, FIG. 1B is a cross-sectional view taken along line I-I′ in FIG. 1A, and FIG. 1C is a partially enlarged view illustrating a region ‘A’of FIG. 1A.

Referring to FIGS. 1A and 1B, a semiconductor package 1a according to an example embodiment may include a base structure 100 and a semiconductor chip 200 stacked in a vertical direction (Z-axis direction). In the present example embodiment, the base structure 100 and the semiconductor chip 200 may have a structure in which elements exposed to an upper surface of the base structure 100 and a lower surface of the semiconductor chip 200 are directly bonded and coupled (for example, by hybrid bonding, direct bonding, or the like), without a separate connection member (e.g., a metal pillar, a solder bump, an adhesive film, or the like). For example, an upper insulating layer 161 providing an upper surface of the base structure 100 and a lower insulating layer 241b providing a lower surface of the semiconductor chip 200 may be directly bonded on a bonding surface of the base structure 100 and the semiconductor chip 200.

The base structure 100 is a semiconductor wafer-based structure, and may be, for example, a silicon interposer substrate, a semiconductor chip, or the like. When the base structure 100 is a semiconductor chip, the base structure 100 and the semiconductor chip 200 may be chiplets constituting a multi-chip module (MCM). In this case, the number of semiconductor chips 200 stacked vertically or horizontally on the base structure 100 may be two or more. For example, the plurality of semiconductor chips 200 on the base structure 100 may include I/O, CPU, GPU, and Field Programmable Gate Array (FPGA) chips, and the like, and the base structure 100 may be an active interposer performing a function of an I/O chip, and in this case, an I/O device, a DC/DC converter, a sensor, a test circuit, and the like may be included therein. For example, the base structure 100 may be a logic chip including a central processor (CPU), a graphics processor (GPU), a field programmable gate array (FPGA), an application processor (AP), a digital signal processor (DSP), an encryption processor, a microprocessor, a microcontroller, an analog-digital converter, an application-specific IC (ASIC), or the like, and the semiconductor chip 200 may be a memory chip such as DRAM, SRAM, PRAM, MRAM, FeRAM, or RRAM. A lower pad 150 and a connection bump SB may be below the base structure 100. The connection bump SB is illustrated in a form of a solder ball, but an embodiment thereof is not limited thereto, and may have a form of a copper pillar or a form in which a copper pillar and a solder ball are combined. According to an example embodiment, the connection bumps SB are omitted and a lower surface of the base structure 100 may form direct bonding with other structures, and in this case, a recess surface may be introduced into the base structure 100, similarly to the semiconductor chip 200.

The semiconductor chip 200 may include a logic chip or a memory chip, and a larger number of semiconductor chips than shown in the drawing may be stacked in a vertical direction (Z-axis direction) or a horizontal direction (X-axis or Y-axis direction) on the base structure 100. In the present inventive concept, a step difference, for example, by forming a recess surface 200R, stepped with a lower surface 200S1 and a side surface 200S2, respectively, at an edge of a bonding surface of the semiconductor chip 200 forming direct bonding, it is possible to reduce or prevent burrs generated in a cutting process (e.g., wafer dicing process) of the chip 200 from protruding to the bonding surface, and as a result, it is possible to provide a planar lower surface 200S1 for stably forming direct bonding, and it is possible to minimize void defects of the semiconductor package 1a and improve the process yield. In addition, in the present inventive concept, by providing the recess surface 200R using specific components of the semiconductor chip 200, the semiconductor chip 200 is capable of minimizing damages to an internal circuit layer (refer to “220” in FIG. 1C) of the semiconductor chip 200 in the wafer dicing process and stably forming direct bonding may be provided.

Hereinafter, each component constituting the bonding surface of the base structure 100 and the semiconductor chip 200 will be described in detail with reference to FIG. 1C.

As illustrated in FIG. 1C, the base structure 100 may include a body 110, an upper pad 165 on the body 110, and an upper insulating layer 161 surrounding or on a side surface of the upper pad 165. The base structure 100 may have a planar upper surface 100S provided by the upper insulating layer 161 and the upper pad 165. In addition, the base structure 100 may further include a through electrode 130 extending through a lower pad (“150” of FIG. 1B) below the body 110 and the upper pad 165 to electrically connect the lower pad 150 and the upper pad 165, and an insulating protective layer 163 between the body 110 and the upper insulating layer 161.

The body 110 may include a semiconductor element such as silicon, germanium, or a semiconductor wafer including a compound semiconductor such as silicon carbide (SiC), gallium arsenide (GaAs), indium arsenide (InAs), and indium phosphide (InP). The body 110 may have an active surface having an active region doped with an impurity and an inactive surface opposing the active region.

The upper pad 165 and the upper insulating layer 161 may be on one surface of the body 110 and provide an upper surface 100S bonded to the semiconductor chip 200. The upper pad 165 may include a conductive material that may be bonded and coupled to the lower connection pad 247 of the semiconductor chip 200, for example, any one of copper (Cu), nickel (Ni), gold (Au), or silver (Ag) or an alloy thereof. The upper insulating layer 161 may include an insulating material that can be bonded and coupled to the lower insulating layer 241 of the semiconductor chip 200 while surrounding a side surface of the upper pad 165, for example, silicon oxide (SiO) or silicon carbonitride (SiCN). An insulating protective layer 163 electrically insulating the upper pad 165 and the body 110 may be between the upper pad 165 and the body 110. The insulating protective layer 163 may include silicon oxide, silicon nitride, silicon carbide, silicon oxynitride, or silicon carbonitride.

The through electrode 130 may extend through the body 110 and the insulating protective layer 164 to electrically connect the upper pad 165 and the lower pad 150. The through electrode 130 may include a via plug 135 and a side insulating film 131 surrounding a side surface of the via plug 135. The side insulating film 131 may electrically separate the via plug 135 from the body 110. The via plug 135 may include, for example, tungsten (W), titanium (Ti), aluminum (Al), or copper (Cu), and may be formed by a plating process, a PVD process, or a CVD process. The side insulating film 131 may include a metal compound such as tungsten nitride (WN), titanium nitride (TiN), or tantalum nitride (TaN), and may be formed by a PVD process or a CVD process.

The semiconductor chip 200 may be on an upper surface 100S of the base structure 100, and may include a substrate 210, a circuit layer 220, and a front structure LS. In addition, the semiconductor chip 200 may have a planar lower surface 200S1 provided by the lower insulating layer 241 and the lower connection pad 247, a side surface 200S2 provided by the lower insulating layer 241 and the substrate 210, and a recess surface 200R extending from one end of the side surface 200S2 to one end of the lower surface 200R1.

The substrate 210 may have a front surface FS having an active region and a rear surface opposite the front surface FS. Individual elements 215 such as transistors may be formed on the front surface FS of the substrate 210. An interlayer insulating film 211 covering the individual elements 215 may be formed on the front surface FS of the substrate, and the individual elements 215 may be connected to a wiring structure 225 of the circuit layer 220 by an interconnection portion 213 (e.g., a contact plug). The interlayer insulating film 211 may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), and Plasma Enhanced Tetra Ethyl Ethyl (PETEOS). Ortho Silicate), Fluoride Silicate Glass (FSG), High Density Plasma (HDP) oxide, Plasma Enhanced Oxide (PEOX), Flowable CVD (FCVD) oxide, or a combination thereof. The individual elements 215 may include FETs such as planar FETs or FinFETs, memory devices such as a flash memory, DRAM, SRAM, EEPROM, PRAM, MRAM, FeRAM, and RRAM, logic devices such as AND, OR, NOT, and various active elements and/or passive elements such as system LSI, CIS, and MEMS.

The circuit layer 220 may include a wiring structure 225 forming an integrated circuit on the front surface FS of the substrate 210 and a low dielectric layer 221 surrounding or on a side surface of the wiring structure 225.

The wiring structure 225 may electrically connect an input/output structure IOS or the input/output pad 245a to the individual elements 215 and the active region of the substrate 210, or interconnect the individual elements 215. The wiring structure 225 may include an electrical test structure (ETS) or a test wiring structure 225ET connecting the test pad 245b to an electrical test circuit. The wiring structure 225 may be formed in a multilayer structure including wiring patterns and wiring vias, may include a metal material, for example, aluminum (Al), gold (Au), cobalt (Co), copper (Cu), nickel (Ni), lead (Pb), tantalum (Ta), tellurium (Te), titanium (Ti), tungsten (W), or a combination thereof.

The low dielectric layer 221 may include a material having a lower dielectric constant than that of the lower insulating layer 241. For example, the low-k layer 221 may be formed of fluorine doped silicon oxide, carbon doped silicon oxide, spin-on silicone based polymer, or a porous layer. For example, fluorine doped silicon oxide may be SiOF, carbon doped silicon oxide may be SiOC, and spin-on silicon-based polymer polymer may be hydrogen silsesquioxane (HSQ), methylsilsesqioxane (MSQ), a poly-tetrafluoroethylene (PTFE) layer, fluorinated poly-aryl-ether (FLARE), poly-paraxylylene, benzo cyclobutene (BCB), silicon low-K polymer (SILK), or the like. In addition thereto, the low dielectric layer 221 may include various materials having a lower dielectric constant than that of the lower insulating layer 241. In the present inventive concept, since a formation region of the recess surface 200R is limited to a region within the lower insulating layer 241, the low dielectric layer 221 may be spaced apart from the recess surface 200R and the side surface 200S2 of the semiconductor chip 200 and may not be exposed thereto. Accordingly, the side surface 200S2 of the semiconductor chip 200 may be provided only by the lower insulating layer 241 and the substrate 210, thereby preventing damage to the circuit layer 220 in the wafer dicing process and stably direct bonding and forming a planar lower surface 200S1 for stably forming direct bonding.

The front structure LS may include an input/output structure IOS, an electrical test structure ETS, a lower connection pad 247, and a lower insulating layer 241.

The input/output structure IOS and the electrical inspection structure ETS may be below a wiring structure 225 and a test wiring structure 225ET, respectively. The test wiring structure 225ET may be between the side surface 200S2 of the semiconductor chip 200 and the wiring structure 225. That is, the input/output structure IOS may be located in a main region MA in which an integrated circuit is formed, and the electrical test structure ETS may be located in the scribe lane SL. The input/output structure IOS and the electrical test structure ETS may be an integral conductive structure including an input/output pad 245a and a test pad 245b, respectively. The electrical test structure ETS may be electrically insulated from the input/output structure IOS. The input/output structure IOS and the electrical test structure ETS may be electrically connected to a wiring structure 225 of the circuit layer 220, and may include, for example, aluminum (Al) or an aluminum (Al) alloy. The input/output pad 245a and the test pad 245b may be on substantially the same level in the lower insulating layer 241 and may be covered by a capping barrier film 243. The capping barrier film 243 may include at least one of, for example, silicon nitride (SiN), silicon carbide (SiC), silicon oxynitride (SiON), silicon carbonitride (SiCN), aluminum nitride (AlN), aluminum oxynitride (AlON), aluminum oxide (AlO), and aluminum oxide carbide (AlOC). The test pad 245b may be covered by an insulating layer after an electrical test is completed. For example, as shown in the drawings, a lower surface of the test pad 245b may be covered by the lower insulating layer 241.

The lower connection pad 247 and the lower insulating layer 241 may be on the front surface FS of the substrate 210 and provide a lower surface 200S1 bonded to the upper surface 100S of the base structure 100. The lower connection pad 247 may be below a wiring structure 225 and the input/output structure IOS, and may include a material for bonding and coupling to the upper pad 165 of the base structure, and may include, at least one of, for example, copper (Cu), nickel (Ni), gold (Au), and silver (Ag), or an alloy thereof. The lower insulating layer 241 may include an insulating material surrounding a side surface of the lower connection pad 247, the input/output structures (IOS), and the electrical test structures (ETS), and capable of being bonded and coupled to the upper insulating layer 161 of the base structure 100, may include, for example, silicon oxide (SiO) or silicon carbonitride (SiCN). The lower insulating layer 241 may be formed by stacking different insulating materials. For example, an insulating barrier film 242 may be between insulating material layers constituting the lower insulating layer 241. The insulating barrier film 242 may include silicon nitride, silicon carbide, silicon oxynitride, or silicon carbonitride.

Meanwhile, to facilitate understanding of the structure and manufacturing process of the front structure LS, it is illustrated that the lower insulating layer 241 is divided into a first lower insulating layer 241a and a second lower insulating layer 241b, however, a boundary between the first lower insulating layer 241a and the second lower insulating layer 241b may not be clearly distinguished. The lower insulating layer 241 may extend from an edge of the semiconductor chip 200 along a side surface of the low dielectric layer 221 to be in contact with the substrate 210 or the interlayer insulating film 211. Accordingly, the lower insulating layer 241 may block the low dielectric layer 221 from being exposed to the side surface 200S2 and the recess surface 200R of the semiconductor chip 200.

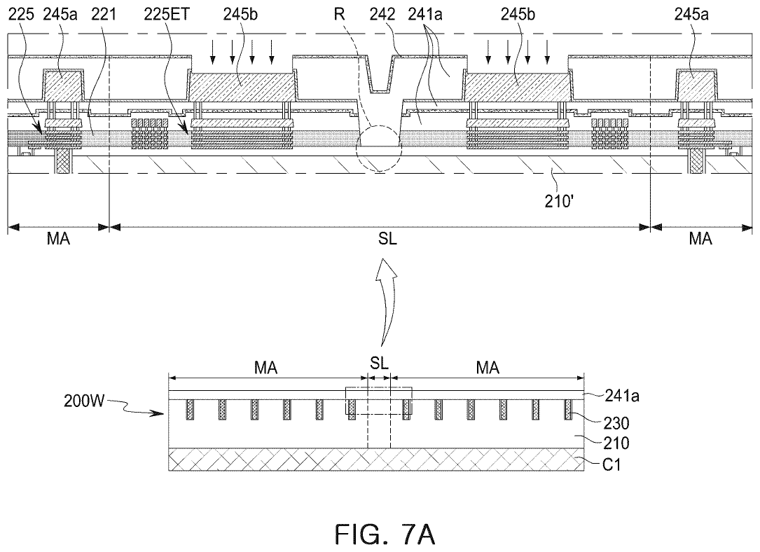

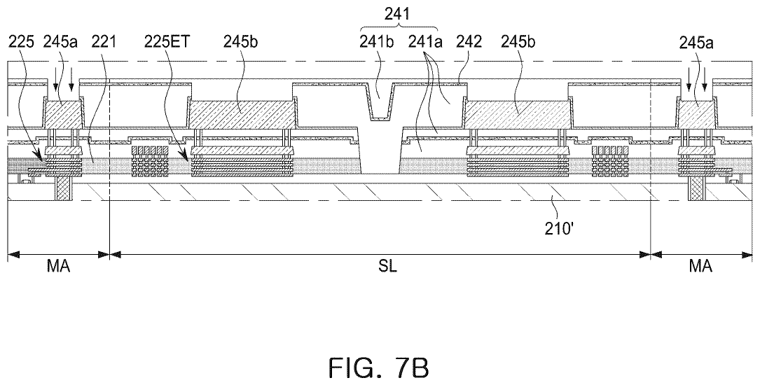

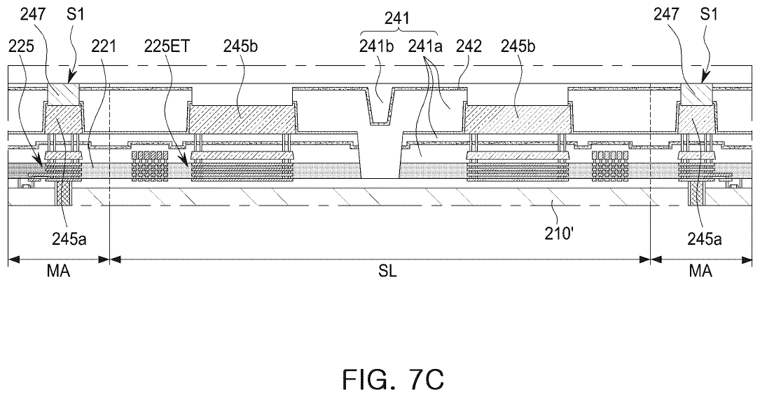

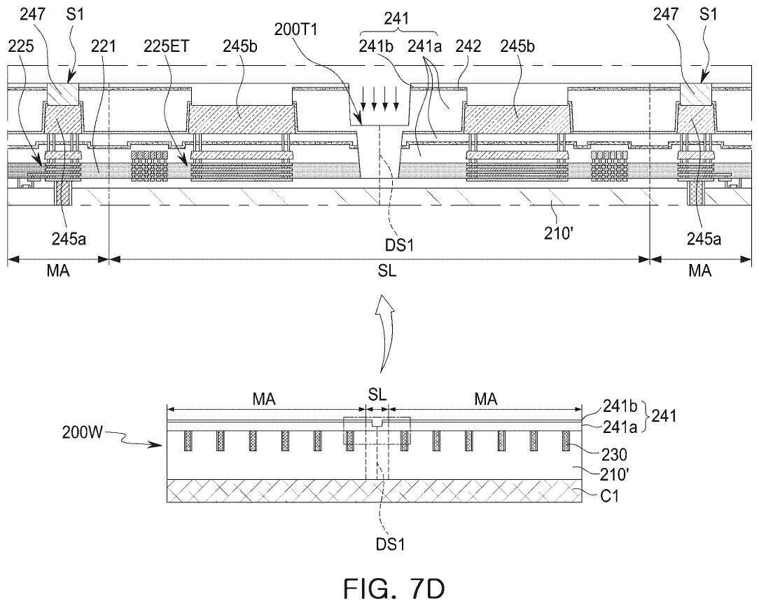

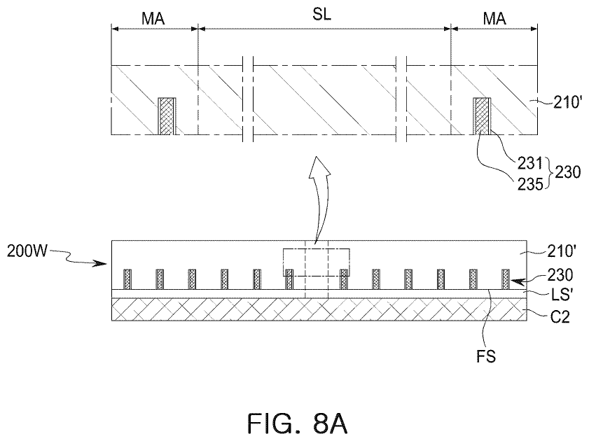

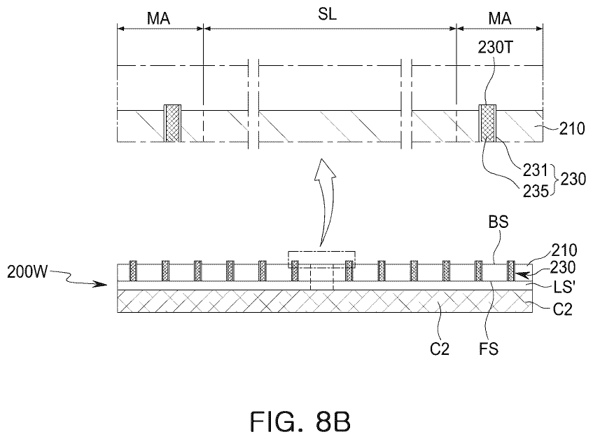

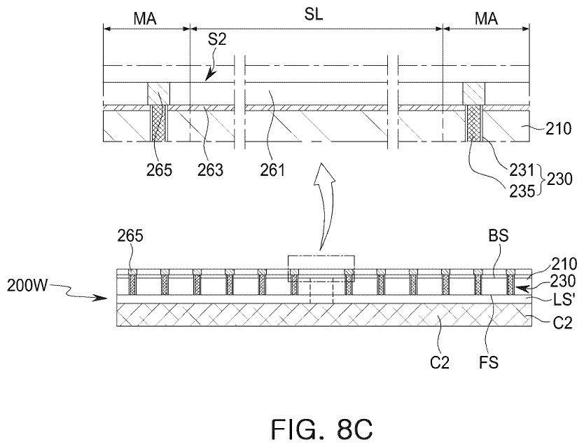

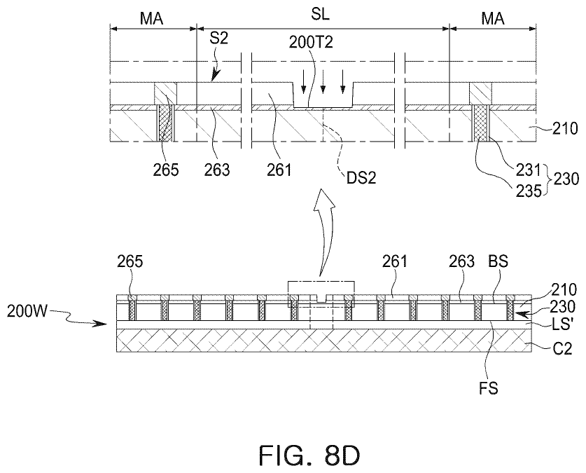

According to the present inventive concept, a recess surface 200R, stepped inwardly from the lower surface 200S1 and the side surface 200S2, respectively, at an edge of a bonding surface of the semiconductor chip 200 for forming direct bonding, so that it is possible to reduce or prevent burrs that protrude into the bonding surface, and as a result, direct bonding may be formed. For example, the recess surface 200R may include a first surface 200R1 recessed in a direction from the lower surface 200S1 toward the substrate 210, and a second surface 200R2 extending from one end of the lower surface 200S1 to the first surface 200R1. Both the first surface 200R1 and the second surface 200R2 may be provided by the lower insulating layer 241, and both of the first surface 200R1 and the second surface 200R2 may be planar surfaces on which the lower insulating layer 241 is etched. When the recess surface 200R is formed by a drying or wet etching process without forming the recess surface 200R using a blade or a laser, burrs generated during a formation process of the recess surface 200R may be controlled (see FIGS. 7D and 8D). The first surface 200R1 may be on a level between the lower surface 200S1 of the semiconductor chip 200 and the front surface FS of the substrate 210, and a lower insulating layer 241 may extend between the first surface 200R1 and the substrate 210. For example, the first surface 200R1 may extend from one end of the side surface 200S2 of the semiconductor chip 200 in a direction parallel to the lower surface 200S1 (X-axis or Y-axis direction). The first surface 200R1 may have a considerable depth so that burrs generated during a cutting process of the semiconductor chip 200 do not protrude to the lower surface 200S1. Accordingly, a separation distanced from the lower surface 200R1 of the semiconductor chip 200 to the first surface 200R1 may have a range of about 5 μm or more, for example, about 5 μm to about 20 μm, or about 5 μm to 15 μm. For example, burrs generated in a dicing process may exist on the first surface 200R1. A depth of the first surface 200R1 or the recess surface 200R may vary depending on process conditions and is not limited to the above numerical range. The second surface 200R2 may extend at a predetermined angle with respect to the first surface 200R1. An angle between the second surface 200R2 and the first surface 200R1 may have a range of about 90 or more, for example, in a range of about 90 degrees to about 130 degrees, about 90 degrees to about 110 degrees, about 90 degrees to about 100 degrees. The angle between the second surface 200R2 and the first surface 200R1 may vary depending on a depth of the recess surface 200R and is not limited to the above numerical range.

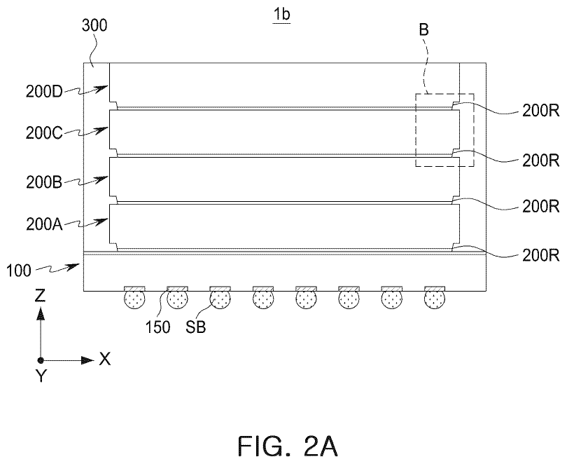

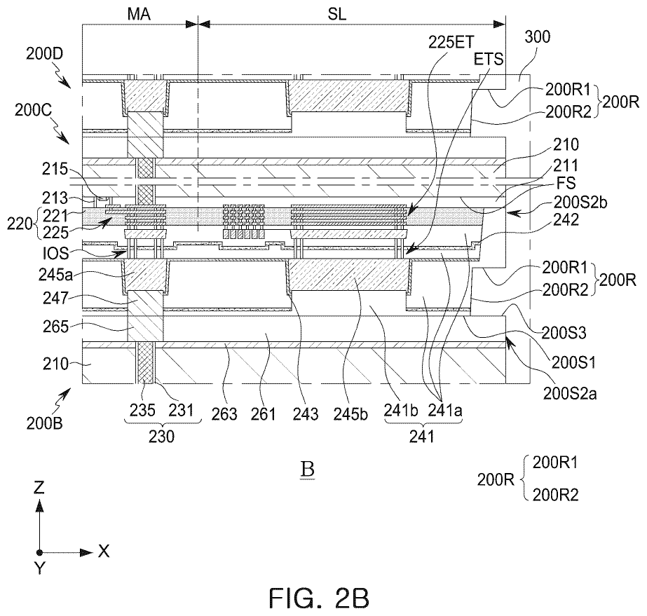

FIG. 2A is a cross-sectional view illustrating a semiconductor package 1b according to an example embodiment of the present inventive concept, and FIG. 2B is a partially enlarged view illustrating a region ‘B’of FIG. 2A.

Referring to FIGS. 2A and 2B, a semiconductor package 1b according to an example embodiment may have the same or similar characteristics as those described with reference to FIGS. 1A to 1C, except that the semiconductor package 1b includes a plurality of semiconductor chips 200A, 200B, 200C, and 200D stacked on the base structure 100. For example, the semiconductor package 1b of the present embodiment may include direct-bonded semiconductor chips 200A, 200B, 200C, and 200D, and a molding member 300. According to an example embodiment, the number of semiconductor chips 200A, 200B, 200C, and 200D may be provided in a greater or lesser amount than that shown in the drawings. For example, three or less or five or more semiconductor chips may be stacked on the base structure 100.

For example, the base structure 100 may be a buffer chip or a control chip including a plurality of logic devices and/or memory devices. The base structure 100 may transmit a signal from the semiconductor chips 200A, 200B, 200C, and 200D stacked thereabove externally, and also transmit a signal and power from the outside to the semiconductor chips 200A, 200B, 200C, and 200D. The semiconductor chips 200A, 200B, 200C, and 200D may include volatile memory devices such as DRAM and SRAM, or non-volatile memory devices such as PRAM, MRAM, FeRAM, or RRAM. In this case, the semiconductor package 1b of the present embodiment may be used for a high bandwidth memory (HBM) product, an electro data processing (EDP) product, or the like.

Since the semiconductor chips 200A, 200B, 200C, and 200D include the same or similar components as the semiconductor chip 200 illustrated in FIGS. 1A to 1C, except that the semiconductor chips 200A, 200B, 200C, and 200D further include a through electrode 230 and an upper connection pad 265 for forming a mutual electrical connection path, reference signs and repeated descriptions for the same components are omitted. The through electrode 230 may include a via plug 235 and a side insulating film 231 surrounding a side surface of the via plug 235. However, unlike the other semiconductor chips 200A, 200B, and 200C, the uppermost semiconductor chip 200D may not include a through electrode 230, and may have a relatively large thickness. In addition, since the through electrode 230, the upper connection pad 265, and the insulating protective layer 263 have the same or similar characteristics as the through electrode 130, the upper pad 165, and the insulating protective layer 163 of the base structure 100 with reference to FIG. 1C, repeated descriptions thereof will be omitted.

Among the semiconductor chips 200A, 200B, 200C, and 200D, an upper insulating layer 261 of the semiconductor chip that is relatively lower and a lower insulating layer 241 of the semiconductor chip that is relatively higher may be coupled while being in contact with each other, and an upper connection pad 255 of the semiconductor chip that is relatively lower and a lower connection pad 247 of the semiconductor chip that is relatively higher may be coupled while being in contact with each other. Accordingly, the semiconductor chips 200A, 200B, 200C, and 200D may be sequentially stacked while the upper insulating layer 261 and the lower insulating layer 241 are coupled while being in contact with each other and the upper contact pad 255 and the lower connection pad 247 are coupled while being in contact with each other. The lowermost semiconductor chip 200A may be coupled while being in contact with the base structure 100.

For example, the semiconductor package 1b of the present example embodiment may include a first semiconductor chip 200B including a first upper connection pad 265 and a first upper insulating layer 261 surrounding a side surface of the first upper connection pad 265, the first semiconductor chip 200B having a first upper surface 200S3 provided by the first upper insulating layer 261 and the first upper connection pad 265 and a first side surface 200S2a provided by the first upper insulating layer 261; and a second semiconductor chip 200C including a second lower connection pad 247 on the first upper surface 200S3 of the first semiconductor chip 200B, and including and facing the first upper connection pad 265 and a second lower insulating layer 241 surrounding a side surface of the second lower connection pad 247, and having a second lower surface 200S1 provided by the second lower connection pad 247 and the second lower insulating layer 241, a second side surface 200S2b provided by the second lower insulating layer 241, and a second recess surface 200R extending from one end of the second side surface 200S2b to one end of the second lower surface 200S1. Here, the first semiconductor chip 200B may be understood as a semiconductor chip that is relatively lower, and the second semiconductor chip 200C may be understood as a semiconductor chip that is relatively higher.

The molding member 300 may be on the base structure 100, and may seal at least a portion of each of the semiconductor chips 200A, 200B, 200C, and 200D. The molding member 300 may be formed to expose an upper surface of an uppermost semiconductor chip 200D. However, according to example embodiments, the molding member 300 may be formed to cover the upper surface of the uppermost semiconductor chip 200D. The molding member 300 may include, for example, an epoxy mold compound (EMC), but a material of the molding member 300 is not particularly limited thereto.

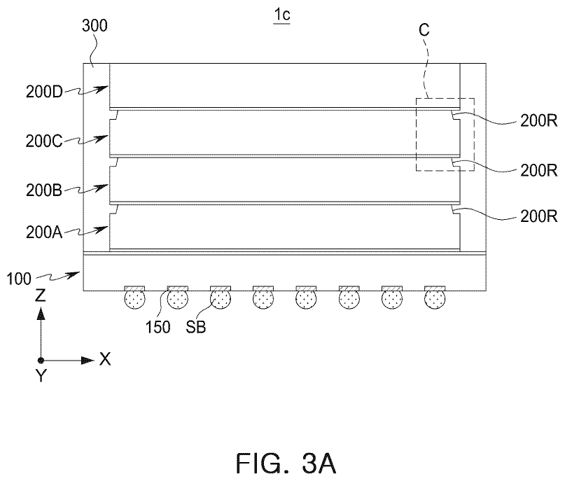

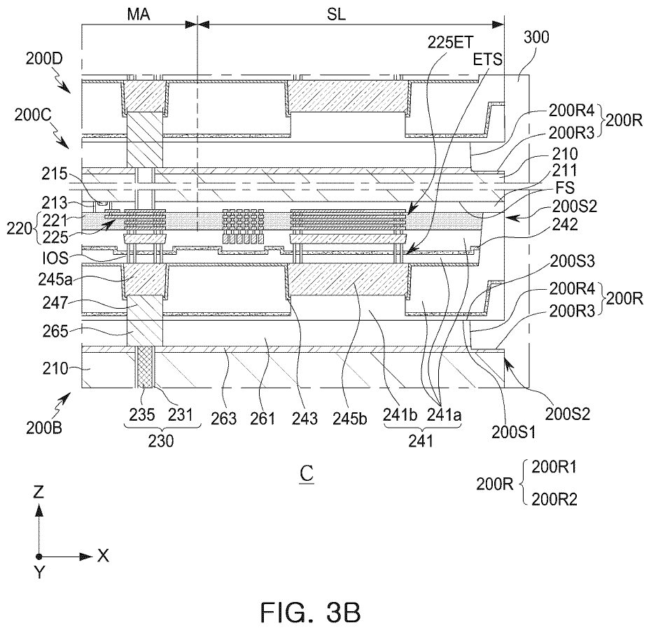

FIG. 3A is a cross-sectional view illustrating a semiconductor package 1c according to an example embodiment of the present inventive concept, and FIG. 3B is a partially enlarged view illustrating a region ‘C’of FIG. 3A.

Referring to FIGS. 3A and 3B, a semiconductor package 1c according to an embodiment may have the same or similar characteristics as those described with reference to FIGS. 1A to 2B, except that a recess surface 200R is formed above semiconductor chips 200A, 200B, 200C, and 200D. Hereinafter, the lowest second semiconductor chip 200A will be mainly described, and reference numerals and repeated descriptions of the same components will be omitted. For example, an upper recess surface 200R (referred to as an “upper” recess surface to distinguish it from the recess surface in FIG. 1A) may extend from one end of a side surface 200S2 of the semiconductor chip 200A to one end of an upper surface 200S3 thereof. The upper recess surface 200R may include a third surface 200R3 extending from one end of the side surface 200S2 of the semiconductor chip 200A and a fourth surface 200R4 extending from one end of the upper surface 200S3 thereof. Similar to the lower recess surface (referred to as a “lower” recess surface to distinguish it from the recess surface of the present example embodiment) described with reference to FIG. 1A, and the like, the upper recess surface 200R may be formed to not to expose the substrate 210. The upper recess surface 200R may be provided by at least one of the upper insulating layer 261 or the insulating protective layer 263, and the upper insulating layer 261 or the insulating protective layer 263 may extend between the upper recess surface 200R and the substrate 210. For example, the upper recess surface 200R may be provided by an upper insulating layer 261 and an insulating protective layer 263, and an insulating protective layer 263 may extend between the third surface 200R3 and the substrate 210. According to an example embodiment, the upper recess surface 200R may be provided only by the upper insulating layer 261, and in this case, the upper insulating layer 261 and the insulating protective layer 263 and the insulating protective layer 263 may extend between the third surface 200R3 and the substrate 210.

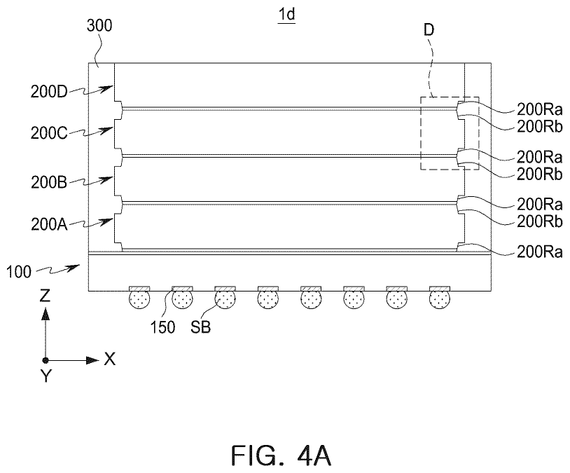

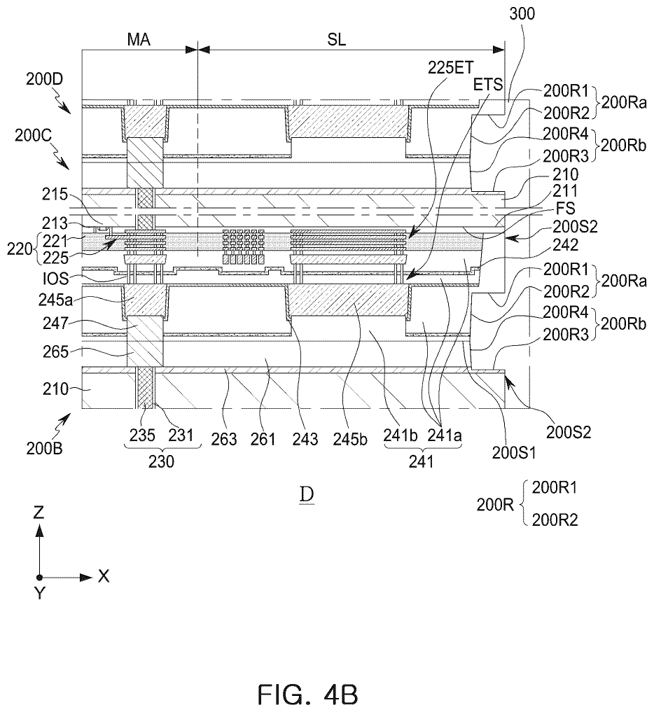

FIG. 4A is a cross-sectional view illustrating a semiconductor package 1d according to an example embodiment of the present inventive concept, and FIG. 4B is a partially enlarged view illustrating a region ‘D’of FIG. 4A.

Referring to FIGS. 4A and 4B, a semiconductor package 1d according to an example embodiment may have the same or similar characteristics as those described with reference to FIGS. 1A to 3B, except that the semiconductor package 1d includes a lower recess surface 200Ra and an upper recess surface 200Rb. The semiconductor chips 200A, 200B, 200C, and 200D may be bonded and coupled so that an upper recess surface 200Rb of the semiconductor chip that is relatively lower and a lower recess surface 200Ra of the semiconductor chip that is relatively higher face each other. For example, the uppermost semiconductor chip 200D may include only the lower recess surface 200Ra. The lower recess surface 200Ra and the upper recess surface 200Rb may be provided by the lower insulating layer 241 and the upper insulating layer 261, respectively. In this case, a groove surrounded by the lower recess surface 200Ra and the upper recess surface 200Rb may be formed, and a space for accommodating burrs generated in a cutting process of the semiconductor chip 200A may be provided.

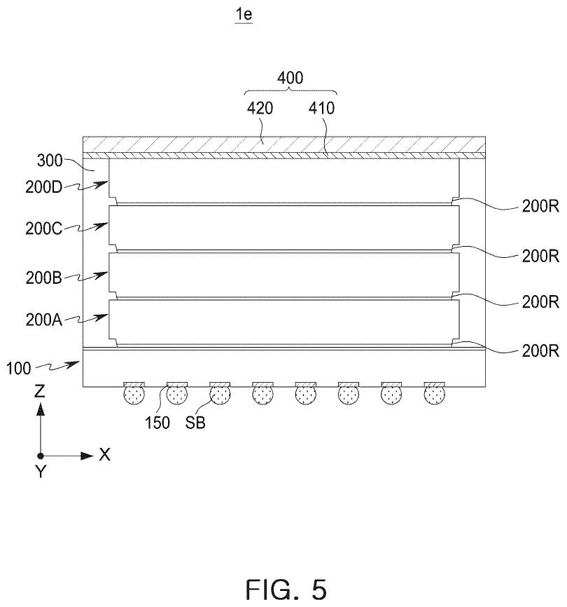

FIG. 5 is a cross-sectional view illustrating a semiconductor package 1e according to an example embodiment of the present inventive concept.

Referring to FIG. 5, a semiconductor package 1e of an example embodiment may have the same or similar characteristics as those described with reference to FIGS. 1A to 4B, except that the semiconductor package 1e further includes a heat dissipation structure 400 on the semiconductor chips 200A, 200B, 200C, and 200D. The heat dissipation structure 400 may be on an uppermost semiconductor chip 200D and a heat dissipation member 300, and for example, may contact an upper surface of the uppermost semiconductor chip 200D exposed from the heat dissipation member 300. The heat dissipation structure 400 may include a heat dissipation plate 420 and an adhesive layer 410 for bonding the heat dissipation plate 420 to the uppermost semiconductor chip 200D and the heat dissipation member 300. The heat dissipation plate 420 may include a material having excellent thermal conductivity, for example, aluminum (Al), gold (Au), silver (Ag), copper (Cu), iron (Fe), graphite (Graphite), graphene (Graphene) and the like. The adhesive layer 410 may include, for example, a thermally conductive adhesive tape, thermally conductive grease, thermally conductive adhesive, and the like.

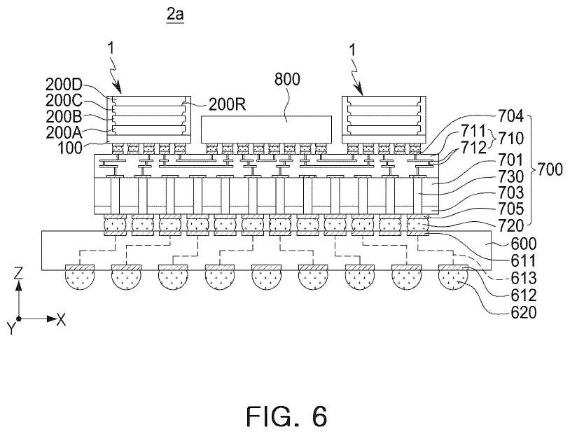

FIG. 6 is a cross-sectional view illustrating a semiconductor package 2a according to an example embodiment of the present inventive concept.

Referring to FIG. 6, a semiconductor package 2a of an example embodiment may include a package substrate 600, an interposer substrate 700, and at least one chip structure 1. In addition, the semiconductor package 2a may further include a logic chip or a processor chip 800 adjacent to the chip structure 1 on the interposer substrate 700. The chip structure 1 The chip structure 1 may have the same or similar characteristics to the semiconductor packages 1a, 1b, 1c, 1d, and 1e described with reference to FIGS. 1A to 5.

The package substrate 600 may be a support substrate on which an interposer substrate 700, a logic chip 800, and a chip structure 1 are mounted, and a substrate for a semiconductor package including a printed circuit board (PCB), a ceramic substrate, a glass substrate, a tape wiring board, and the like. A body of the package substrate 600 may include different materials depending on the type of the substrate. For example, when the package substrate 600 is a printed circuit board, it may be in a form in which a wiring layer is additionally laminated on one or both sides of a body copper clad laminate or a copper clad laminate.

The interposer substrate 700 may include a substrate 701, a lower protective layer 703, a lower pad 705, an interconnection structure 710, a metal bump 720, and a through via 730. The chip structure 1000 and the processor chip 800 may be stacked on the package substrate 600 via the interposer substrate 700. The interposer substrate 700 may electrically connect the chip structure 1000 and the processor chip 800 to each other.

The substrate 701 may be formed of, for example, any one of silicon, an organic material, plastic, and a glass substrate. When the substrate 701 is a silicon substrate, the interposer substrate 700 may be referred to as a silicon interposer, and may be manufactured through the process described with reference to FIGS. 1 to 7. Unlike those illustrate in the drawings, when the substrate 701 is an organic substrate, the interposer substrate 700 may be referred to as a panel interposer.

A lower protective layer 703 may be on a lower surface of the substrate 701, and a lower pad 705 may be on the lower protective layer 703. The lower pad 705 may be connected to the through via 730. The chip structure 1000 and the processor chip 800 may be electrically connected to the package substrate 600 through the metal bumps 720 on the lower pad 705.

The interconnection structure 710 may be on an upper surface of the substrate 701, and may include an interlayer insulating layer 711 and a single-layer or multilayer wiring structure 712. When the interconnection structure 710 has a multilayer wiring structure, wiring patterns of different layers may be connected to each other through contact vias.

The through via 730 may extend from an upper surface to a lower surface of the substrate 701 to extend through the substrate 701. In addition, the through via 730 may extend into the interconnection structure 710 to be electrically connected to wirings of the interconnection structure 710. When the substrate 701 is silicon, the through via 730 may be referred to as a TSV. According to an example embodiment, the interposer substrate 700 may include only an interconnection structure therein, but may not include a through via.

The interposer substrate 700 may be used for the purpose of converting or transferring an input electrical signal between the package substrate 600 and the chip structure 1 or the processor chip 800. Accordingly, the interposer substrate 700 may not include elements such as active elements or passive elements. Also, according to an example embodiment, the interconnection structure 710 may be below a through via 730. For example, a positional relationship between the interconnection structure 710 and the through via 730 may be relative.

The metal bump 720 may be on a lower surface of the interposer substrate 700 and may be electrically connected to a wiring of the interconnection structure 710. The interposer substrate 700 may be stacked on the package substrate 600 through a metal bump 720 The metal bump 720 may be connected to the lower pad 705 through wirings of the interconnection structure 710 and the through via 730. In one example, a portion of lower pads 705 used for power or ground among the lower pads 705 may be integrated and connected together to the metal bump 720, so that the number of the lower pads 705 may be greater than or equal to the number of the metal bump 720.

The logic chip or processor chip 800 may include, for example, a central processor (CPU), a graphics processor (GPU), a field programmable gate array (FPGA), a digital signal processor (DSP), a cryptographic processor, a microprocessor, a microcontroller, an analog-to-digital converter, an application specific integrated circuit (ASIC), and the like. Depending on the types of devices included in the logic chip 800, the semiconductor package 2a may be referred to as a server-oriented semiconductor package or a mobile-oriented semiconductor package.

Meanwhile, the semiconductor package 2a may further include an internal sealing material covering a side surface and an upper surface of the chip structure 1 and the processor chip 800 on the interposer substrate 700. In addition, the semiconductor package 2a may further include an outer sealing material covering the interposer substrate 700 and the inner sealing material on the package substrate 600. The outer sealing material and the inner sealing material may be formed together and may thus be indistinguishable. According to an example embodiment, the semiconductor package 2a may further include a heat dissipation structure covering the chip structure 1 and the processor chip 800 on the package substrate 600.

FIGS. 7A to 7D are cross-sectional views illustrating a manufacturing process of a semiconductor chip according to a process sequence according to an example embodiment of the present inventive concept. FIGS. 7A to 7D illustrate a manufacturing process of a recess surface or a “lower” recess surface of the semiconductor chip illustrated in FIG. 1A and the like.

Referring to FIG. 7A, an electrical test may be performed using a test pad 245b of a semiconductor wafer 200W. The semiconductor wafer 200W may be adhered to a first carrier C1, which may be in a state in which components for semiconductor chips may be implemented. For example, the semiconductor wafer 200W may include a wiring structure 225, a low dielectric layer 221, an input/output pad 245a, a test pad 245b, a first lower insulating layer 241a, and the like, on a preliminary substrate 210′ before a thickness is adjusted by a backgrinding process. Here, the input/output pad 245a may be located in a main region MA, and the test pad 245b may be located in a scribe lane SL. The first lower insulating layer 241a may extend to cut the low dielectric layer 221 in a partial region R of the scribe lane SL. The electrical test of the semiconductor wafer 200W may be performed by etching a portion of the first lower insulating layer 241a to expose the test pad 245b. After the electrical test, a pile-up on a surface of the test pad 245b may be removed to prevent undulation of the second lower insulating layer 241b to be formed later.

Referring to FIG. 7B, a second lower insulating layer 241b may be formed and processed to expose the input/output pad 245a. The second lower insulating layer 241b may include a silicon oxide, but an embodiment thereof is not limited thereto. According to an example embodiment, the second lower insulating layer 241b may include at least one of silicon nitride (SiN), silicon carbide (SiC), silicon oxynitride (SiON), silicon carbonitride (SiCN), aluminum nitride (AlN), aluminum oxynitride (AlON), aluminum oxide (AlO), and aluminum oxide carbide (AlOC). An interface between the first lower insulating layer 241a and the second lower insulating layer 241b may not be clearly distinguished.

Referring to FIG. 7C, a lower connection pad 247 may be formed on the input/output pad 245a. The lower connection pad 247 may be formed by filling an opening of the lower insulating layer 241 with a metal such as copper (Cu) using a plating process. The lower connection pad 247 may be formed to be coplanar with the lower insulating layer 241 by performing a planarization process such as a chemical mechanical polishing (CMP) process after the plating process. That is, an upper surface of the lower connection pad 247 and an upper surface of the lower insulating layer 241 may provide a first planar surface S1.

Referring to FIG. 7D, a first trench 200T1 may be formed by processing a lower insulating layer 241. The second trench 200T1 may be formed by etching the lower insulating layer 241, and may have a shape (e.g., trapezoid) in which a width thereof toward a lower portion decreases. The lower insulating layer 241 extending through the low dielectric layer 221 may be below the first trench 200T1. The first trench 200T1 may have a predetermined depth so that burrs generated in a dicing process of the semiconductor wafer 200W for cutting a first dividing surface DS1 do not protrude onto a first planar surface S1. For example, the first trench 200T1 may have a depth of about 5 μm or more. Also, the first trench 200T1 may have a width greater than a width of the first dividing surface DS1 removed in the dicing process. In the drawing, although the first dividing section DS1 is illustrated by a dotted line, it can be understood as a region having a predetermined volume in consideration of the region removed in the dicing process. The first trench 200T1 may provide a recess surface (or a “lower” recess surface) of the semiconductor chip after the dicing process of the semiconductor wafer 200W.

FIGS. 8A to 8D are cross-sectional views illustrating a manufacturing process of a semiconductor chip according to an example embodiment of the present inventive concept. FIGS. 8A to 8D illustrate the manufacturing process of the recess surface or “upper” recess surface of the semiconductor chip shown in FIG. 3A and the like.

Referring to FIG. 8A, a semiconductor wafer 200W on which a front structure layer LS′ is formed may be temporarily bonded to a second carrier C2. The semiconductor wafer 200W may be stably supported on the second carrier C2 during a subsequent process by an adhesive material layer such as glue. The semiconductor wafer 200W may be positioned such that a front surface FS of a preliminary substrate 210′ faces the second carrier C2. The front structure layer LS′ may be formed through the processes of FIGS. 7A to 7D. According to an example embodiment, the front structural layer LS′ may not include a recess surface.

Referring to FIG. 8B, a thickness of the semiconductor wafer 200W may be reduced by applying a polishing process to an upper surface (an inactive surface) of the semiconductor wafer 200W. As a portion of the preliminary substrate 210′ of FIG. 8A is removed, an upper end 230T of a through electrode 230 may protrude from a rear surface BS of the substrate 210. The polishing process may be a CMP process, an etch-back process, or a combination thereof. For example, a CMP process may be performed to reduce a predetermined thickness of the semiconductor wafer 200W, and an etch-back having an appropriate condition may be applied to sufficiently expose the through electrode 230.

Referring to FIG. 8C, an insulating protective layer 263, an upper insulating layer 261, and an upper connection pad 265 may be sequentially formed on the rear surface BS of the substrate 210. The insulating protective layer 263 may be a silicon oxide. In some example embodiments, a buffer film including a silicon nitride or a silicon oxynitride may be formed above the insulating protective layer 263. The upper insulating layer 261 may include a silicon oxide, but an embodiment thereof is not limited thereto. The upper connection pad 265 may be formed to be coplanar with the upper insulating layer 261 through a plating process and a planarization process. That is, an upper surface of the upper connection pad 265 and an upper surface of the upper insulating layer 261 may provide a second planar surface S2.

Referring to FIG. 8D, a second trench 200T2 may be formed by processing an upper insulating layer 261. For example, the second trench 200T2 may be formed by etching the upper insulating layer 261 and the insulating protective layer 263, and may have a shape (e.g., trapezoid) in which a width thereof toward a lower portion decreases. The second trench 200T2 may be formed to a depth in which the rear surface BS of the substrate 210 is not exposed. The second trench 200T2 may have a predetermined depth so that burrs generated in a dicing process of the semiconductor wafer 200W for cutting a second dividing surface DS2 do not protrude onto the second planar surface S2. In addition, the second trench 200T2 may have a width greater than a width of the second dividing surface DS2 removed in the dicing process. In the drawing, although the second dividing section DS2 is illustrated by a dotted line, it can be understood as a region having a predetermined volume in consideration of the region removed in the dicing process. The second trench 200T2 may provide a recess surface (or an “upper” recess surface) of the semiconductor chip after the dicing process of the semiconductor wafer 200W.

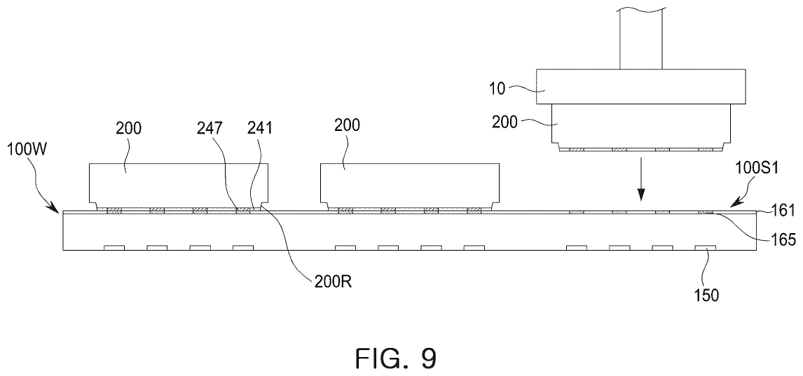

FIG. 9 is a cross-sectional view illustrating a manufacturing process of a semiconductor package according to an example embodiment of the present inventive concept.

Referring to FIG. 9, a semiconductor chip 200 may be on a base wafer 100W. The base wafer 100W may include components for the base structure 100 of FIG. 1A. The semiconductor chip 200 may be on the base wafer 100W using a pick-and-place device 10. A lower surface of the semiconductor chip 200 provided by the lower insulating layer 241 and the lower connection pad 247 and an upper surface of the base structure 100 provided by the upper insulating layer 161 and the upper pad 165 may be bonded to each other. Since the semiconductor chip 200 includes a recess surface 200R, a planar lower surface in which burrs do not protrude may be provided. The lower insulating layer 241 and the upper insulating layer 161, and the lower connection pad 247 and the upper connection pad 165 may be subjected to pressure in a temperature atmosphere, higher than room temperature, for example, in a thermal atmosphere of about 200° C. to about 300° C. and bonded and coupled with each other. Here, a temperature of the thermal atmosphere is not limited to about 200° C. to about 300° C., and may be variously changed.

As set forth above, according to example embodiments of the present inventive concept, a semiconductor chip having a reduced burr protruding onto a bonding surface, and a semiconductor package in which void defects are minimized and yield is improved may be provided.

Herein, a lower side, a lower portion, a lower surface, and the like, are used to refer to a direction toward a mounting surface of the fan-out semiconductor package in relation to cross-sections of the drawings, while an upper side, an upper portion, an upper surface, and the like, are used to refer to a direction opposite to the direction. However, these directions are defined for convenience of explanation, and the claims are not limited by the directions defined as described above.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an example embodiment” used herein does not refer to the same example embodiment and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

Terms used herein are used only to describe an example embodiment rather than limiting the present disclosure. In this case, singular forms include plural forms unless interpreted otherwise in context.

While example embodiments have been shown and described above, it will be apparent to those skilled in the art that modifications and variations could be made without departing from the scope of the present inventive concept as defined by the appended claims.

What is claimed is:

1. A method for manufacturing a semiconductor package comprising:
forming a semiconductor wafer comprising:
a substrate having main regions and a scribe region between the main regions,
a wiring structure on the main regions,
at least one test wiring structure on the scribe region,
a low dielectric layer surrounding a lower portion of the wiring structure and a lower portion of the at least one test wiring structure,
an input/output pad on the wiring structure,
at least one test pad on the at least one test wiring structure, and
a first insulating layer surrounding an upper portion of the wiring structure, an upper portion of the at least one test wiring structure and covering the input/output pad and the at least one test pad,
wherein the first insulating layer has at least one first opening on the at least one test pad and a partial region separating the low dielectric layer within the scribe region;
performing an electrical test through the at least one test pad;
forming a second insulating layer on the first insulating layer, the second insulating layer having a second opening on the input/output pad;
forming a connection pad in the second opening;
forming a recess extending from an upper surface of the second insulating layer toward the partial region, the recess having a lateral wall provided by the first insulating layer and the second insulating layer, and a bottom provided by the first insulating layer; and
dicing the semiconductor wafer along a dividing lane, the dividing lane passing through the bottom of the recess, the partial region of the first insulating layer, and the substrate.

2. The method of claim 1, wherein:
the scribe region is disposed between adjacent ones among the main regions in a lateral direction,
the semiconductor wafer comprises a first test wiring structure and a second test wiring structure spaced apart from each other in the lateral direction,
the low dielectric layer comprises a first section surrounding the first test wiring structure and a second section surrounding the second test wiring structure, and
the first section and the second section are spaced apart from each other by the partial region of the first insulating layer.

3. The method of claim 1, wherein the at least one first opening is formed by etching the first insulating layer on the at least one test pad.

4. The method of claim 1, wherein the low dielectric layer includes a material having a dielectric constant lower than each of a dielectric constant of the first insulating layer and a dielectric constant of the second insulating layer.

5. The method of claim 1, wherein the second insulating layer is disposed in the at least one first opening.

6. The method of claim 1, wherein the second opening is formed by etching the second insulating layer on the input/output pad.

7. The method of claim 1, wherein the second insulating layer includes silicon oxide or silicon carbonitride.

8. The method of claim 1, wherein the connection pad is disposed in the second opening.

9. The method of claim 1, wherein an upper surface of the connection pad and an upper surface of the second insulating layer are coplanar with each other.

10. The method of claim 1, wherein:
the scribe region is disposed between adjacent ones among the main regions in a lateral direction,
the recess extends through the second insulating layer in a vertical direction perpendicular to the lateral direction.

11. The method of claim 10, wherein the bottom of the recess overlaps the at least one test pad in the lateral direction.

12. The method of claim 10, wherein the bottom of the recess extends in the lateral direction and the lateral wall of the recess extends upwardly from an edge of the bottom of the recess.

13. The method of claim 12, wherein the lateral wall of the recess has an angle of 90 degrees or more with respect to the bottom of the recess.

14. The method of claim 10, wherein a distance from an upper surface of the second insulating layer to the bottom of the recess in the vertical direction is 5 μm or more.

15. The method of claim 10, wherein:
the dividing lane has a first width in the lateral direction,
the partial region has a second width in the lateral direction,
the recess has a third width in the lateral direction, and
the first width is smaller than each of the second width and the third width.

16. A method for manufacturing a semiconductor package comprising:
forming a semiconductor wafer comprising:
a substrate having main regions and a scribe region between the main regions,
at least one test wiring structure on the scribe region,
a low dielectric layer surrounding a lower portion of the at least one test wiring structure,
at least one test pad on the at least one test wiring structure, and
a first insulating layer surrounding an upper portion of the at least one test wiring structure and covering the at least one test pad, the first insulating layer having a partial region separating the low dielectric layer in a lateral direction within the scribe region;
performing an electrical test through the at least one test pad;
forming a second insulating layer on the first insulating layer, the second insulating layer covering the at least one test pad;
forming a recess having a lateral wall provided by the first insulating layer and the second insulating layer, and a bottom provided by the first insulating layer; and
dicing the semiconductor wafer along a dividing lane, the dividing lane passing through the bottom of the recess, the partial region of the first insulating layer, and the substrate.

17. The method of claim 16, wherein the recess extends from an upper surface of the second insulating layer toward the partial region.

18. The method of claim 16, wherein the first insulating layer is interposed between the recess and the low dielectric layer.

19. The method of claim 18, wherein the bottom of the recess is spaced apart from the low dielectric layer.

20. A method for manufacturing a semiconductor package comprising:
forming a semiconductor wafer comprising:
a first test wiring structure and a second test wiring structure spaced apart from each other in a lateral direction,
a low dielectric layer comprising a first section on a lower portion of the first test wiring structure, and a second section on a lower portion of the second test wiring structure,
at least one test pad on each of the first and second test wiring structures, and
a first insulating layer on upper portions of the first and second test wiring structures,
wherein the first section and the second section are spaced apart from each other by the first insulating layer;
forming a second insulating layer on the first insulating layer and the at least one test pad;
forming a recess extending downwardly from an upper surface of the second insulating layer between the first and second test wiring structures; and
dicing the semiconductor wafer passing between the first section and the second section of the low dielectric layer.
